(19) United States
(12) Patent Application Publication
(10) Pub. No.: US 2023/0043101 A1
(43) Pub. Date: Feb. 9, 2023

(54) OPTICAL SYSTEM AND METHOD OF FORMING THE SAME

(71) Applicants: Agency for Science, Technology and Research, Singapore (SG); ams AG, Premstaetten (AT)

(72) Inventors: Zhengtong Liu, Singapore (SG); Jinghua Teng, Singapore (SG); Hong Son Chu, Singapore (SG); Qian Wang, Singapore (SG); Jie Deng, Singapore (SG); Soo Seng Norman Ang, Singapore (SG); Xiao Song Eric Tang, Singapore (SG); Ching Eng Jason Png, Singapore (SG); Gernot Fasching, Premstaetten (AT); Lijian Mai, Singapore (SG); Anderson Singulani, Premstaetten (AT); Jozef Pulko, Premstaetten (AT)

(21) Appl. No.: 17/789,166

(22) PCT Filed: Jan. 14, 2021
(86) PCT No.: PCT/SG2021/050026

§ 371 Date: Jun. 24, 2022

(30) Foreign Application Priority Data
Jan. 17, 2020 (SG) 10202000487W

(51) Int. Cl. G02B 27/09; G03F 7/00

(52) U.S. Cl. CPC G02B 27/0955; G03F 7/0005; G02B 2207/101

(57) ABSTRACT

Various embodiments may relate to an optical system. The optical system may include a lens structure configured to generate an outgoing Gaussian beam based on an incoming Gaussian beam. The optical system may also include a light source configured to provide the incoming Gaussian beam to the lens structure. The lens structure may be a flat lens or a phase plate.

### CROSS-REFERENCE TO RELATED APPLICATION

This application claims the benefit of priority of Singapore application No. 10202000487W filed Jan. 17, 2020, the contents of it being hereby incorporated by reference in its entirety for all purposes.

### TECHNICAL FIELD

Various embodiments of this disclosure may relate to an optical system. Various embodiments of this disclosure may relate to a method of forming an optical system.

### BACKGROUND

Gaussian beam is one of the most commonly used and thoroughly studied monochromatic electromagnetic waves. In general, any solutions of the paraxial Helmholtz equation can be expressed by Hermite-Gaussian modes when using Cartesian coordinates or by Laguerre-Gaussian modes when using cylindrical coordinates.

Single mode lasers usually have Gaussian beam outputs, and they are used in many applications, such as optical fiber communications, laser scanners and Light Detection and Ranging (LiDAR) systems. In real applications the Gaussian beams from lasers often need to go through some optics like lens, which will introduce wave front transformation. The two most used Gaussian beam transformations are beam focusing and beam collimation. FIG. 1 shows Gaussian beam transformations. While conventional lenses can perform those functionalities to certain extents, they are not designed to work with Gaussian beams and do not provide the exact phase changes needed for Gaussian beam transformation, so substantial aberrations are inevitable.

### SUMMARY

Various embodiments may relate to an optical system. The optical system may include a lens structure configured to generate an outgoing Gaussian beam based on an incoming Gaussian beam. The optical system may also include a light source configured to provide the incoming Gaussian beam to the lens structure. The lens structure may be a flat lens or a phase plate.

Various embodiments may relate to a method of forming an optical system. The method may include forming a lens structure configured to generate an outgoing Gaussian beam based on an incoming Gaussian beam provided by a light source. The lens structure may be a flat lens or a phase plate.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 shows Gaussian beam transformations.

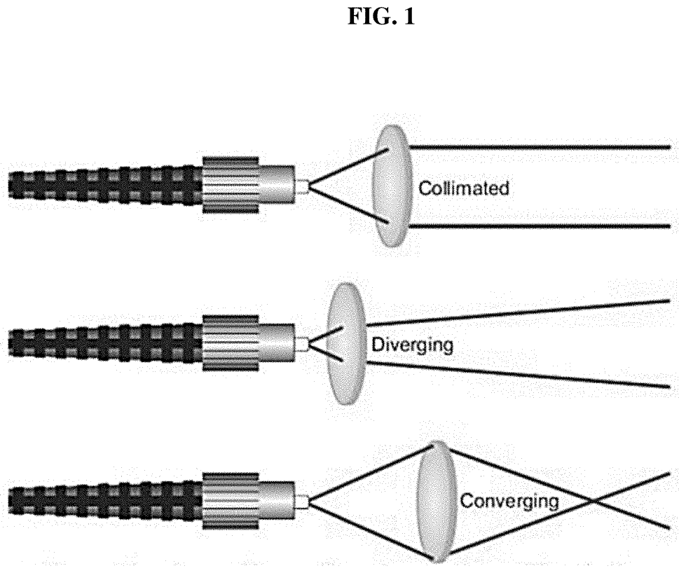

FIG. 2 is a general illustration of an optical system according to various embodiments.

FIG. 3 is a general illustration of a method of forming an optical system according to various embodiments.

FIG. 4 is a schematic illustrating the transformation of an input Gaussian beam to an output Gaussian beam by a flat lens or a phase plate according to various embodiments.

FIG. 5 is a schematic illustrating the transformation of an input Gaussian beam to an output Gaussian beam by a flat lens or a phase plate in which the input medium is of refractive index nᵢₙ and the output medium is of refractive index nₒᵤₜ according to various embodiments.

FIG. 6 is a schematic showing an optical system according to various embodiments.

FIG. 7 shows a plot of magnitude as a function of pillar diameter (in nanometers or nm) illustrating the phase change and transmission of an array of circular pillars with different diameters according to various embodiments.

FIG. 8A shows a perspective view of a full lens structure including a plurality of pillars and a glass substrate according to various embodiments.

FIG. 8B shows a top view of a full lens structure as shown in FIG. 8A according to various embodiments.

FIG. 8C shows a plot of pillar diameter (in nanometers or nm) as a function of ring radius (in micrometers or μm) showing the distribution of pillar diameters across the ring radius of a lens according to various embodiments.

FIG. 9A shows (above) the field intensity along the xz cross section generated by an optical system according to various embodiments; and (below) a plot of intensity as a function of distance along the z direction (in micrometers or μm) illustrating the variation of intensity along the dashed line shown according to various embodiments.

FIG. 9B shows (middle) the field intensity along the xy cross section generated by the optical system according to various embodiments; (top) a linear scale plot of intensity as a function of distance along the x direction (in micrometers or μm) illustrating the variation of intensity along the dashed line according to various embodiments; and (bottom) a plot of intensity (in decibels or dB) as a function of distance along the x direction (in micrometers or μm) illustrating the variation of intensity along the dashed line according to various embodiments

FIG. 9C shows (left) the field intensity along the xz cross section generated by another optical system according to various embodiments; and (right) a plot of intensity as a function of distance along the z direction (in micrometers or μm) illustrating the variation of intensity along the dashed line shown according to various embodiments.

FIG. 9D shows (top) the field intensity along the xz cross section generated by another optical system according to various embodiments; and (bottom) a plot of intensity as a function of distance along the z direction (in micrometers or μm) illustrating the variation of intensity along the dashed line shown according to various embodiments.

FIG. 10A shows (left) the field intensity along the xz cross section generated by full lens simulation based on plane wave excitation; (top right) a plot of intensity as a function of distance along the x direction (in micrometers or μm) illustrating the variation of intensity along the horizontal dashed line shown; and (bottom right) a plot of intensity as a function of distance along the z direction (in micrometers or μm) illustrating the variation of intensity along the vertical dashed line shown.

FIG. 10B shows (top) the field intensity along the xz cross section generated based on a Gaussian beam excitation; (bottom left) the field intensity along the xy cross section generated based on the Gaussian beam excitation; and (bottom right) a plot of intensity as a function of distance along the x direction (in micrometers or μm) illustrating the variation of intensity along the x direction.

FIG. 10C shows (top) the field intensity along the xz cross section generated based on another Gaussian beam excitation; (bottom left) the field intensity along the xy cross section generated based on the Gaussian beam excitation; and (bottom right) a plot of intensity as a function of distance along the x direction (in micrometers or μm) illustrating the variation of intensity along the x direction.

FIG. 11A shows a schematic of a collimating lens and the intensities of the outgoing Gaussian beam from the collimating lens at several points according to various embodiments.

FIG. 11B shows a plot of normalized intensity as a function of distance along the x-direction (in micrometer or μm) of the full lens simulations of the lens shown in FIG. 11A according to various embodiments.

FIG. 12 shows a plot of beam size (in micrometer or μm) as a function of distance (in micrometer or μm) comparing theoretical calculation and full lens simulation of beam sizes captured at different distances when a Gaussian beam passes through the collimating lens according to various embodiments.

FIG. 13A is a scanning electron microscopy (SEM) image showing a top view of a fabricated flat lens according to various embodiments.

FIG. 13B is another scanning electron microscopy (SEM) image showing a tilted, magnified view of FIG. 13A according to various embodiments. FIG. 13B shows details of the individual pillars.

FIG. 14 is a schematic showing an optical testing step up or optical system according to various embodiments.

FIG. 15A shows (top) the image of the Gaussian beam after passing through the 393 μm focusing flat lens with a focal length (f) of 1000 μm according to various embodiments; and (bottom) a plot of intensity as a function of distance (in micrometers or μm) illustrating the x-cut line profile of the Gaussian beam shown according to various embodiments.

FIG. 15B shows (top) the image of the Gaussian beam after passing through the 393 μm focusing flat lens with a focal length (f) of 500 μm according to various embodiments; and (bottom) a plot of intensity as a function of distance (in micrometers or μm) illustrating the x-cut line profile of the Gaussian beam shown according to various embodiments.

FIG. 15C shows (top) the image of the Gaussian beam after passing through the 393 μm focusing flat lens with a focal length (f) of 200 μm according to various embodiments; and (bottom) a plot of intensity as a function of distance (in micrometers or μm) illustrating the x-cut line profile of the Gaussian beam shown according to various embodiments.

FIG. 16A shows (top) the image of the Gaussian beam after passing through the collimating lens at z position=0 (which is an arbitrary position) according to various embodiments; and (bottom) a plot of intensity as a function of distance (in micrometers or μm) illustrating the x-cut line profile of the Gaussian beam shown according to various embodiments.

FIG. 16B shows (top) the image of the Gaussian beam after passing through the collimating lens at z position=2.5 cm according to various embodiments; and (bottom) a plot of intensity as a function of distance (in micrometers or μm) illustrating the x-cut line profile of the Gaussian beam shown according to various embodiments.

FIG. 16C shows (top) the image of the Gaussian beam after passing through the collimating lens at z position=5 cm according to various embodiments; and (bottom) a plot of intensity as a function of distance (in micrometers or μm) illustrating the x-cut line profile of the Gaussian beam shown according to various embodiments.

FIG. 16D shows (top) the image of the Gaussian beam after passing through the collimating lens at z position=7.5 cm according to various embodiments; and (bottom) a plot of intensity as a function of distance (in micrometers or μm) illustrating the x-cut line profile of the Gaussian beam shown according to various embodiments.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the optical systems/structures or methods are analogously valid for the other optical systems/structures or methods. Similarly, embodiments described in the context of a method are analogously valid for an optical system/structure, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The member or assembly as described herein may be operable in various orientations, and thus it should be understood that the terms “top”, “bottom”, etc., when used in the following description are used for convenience and to aid understanding of relative positions or directions, and not intended to limit the orientation of the optical system/structure.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

Various embodiments may involve fundamental Gaussian modes. Accordingly, Gaussian beams may refer to fundamental Gaussian mode beams.

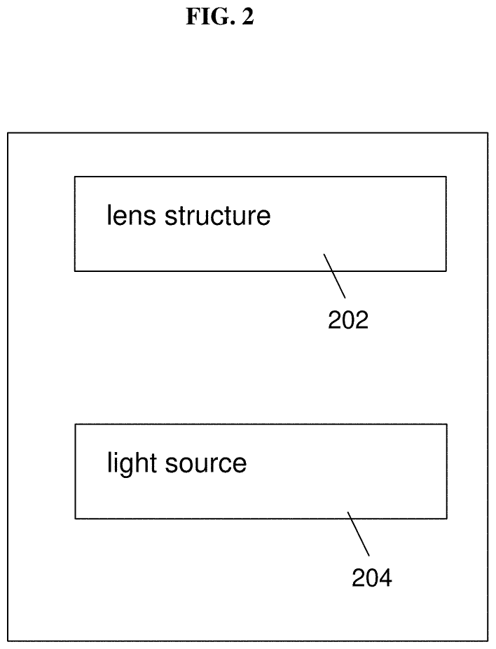

FIG. 2 is a general illustration of an optical system according to various embodiments. The optical system may include a lens structure 202 configured to generate an outgoing Gaussian beam based on an incoming Gaussian beam. The optical system may also include a light source 204 configured to provide the incoming Gaussian beam to the lens structure 202. The lens structure 202 may be a flat lens or a phase plate.

In other words, the optical system may include a light source 204 which generate a Gaussian beam. The optical system may also include a lens structure 202, i.e. a flat lens or a phase plate which transforms the Gaussian beam (referred to as an incoming Gaussian beam) to another Gaussian beam, i.e. the outgoing Gaussian beam.

The light source 204 may be a laser (alternatively referred to as a laser source), e.g. a vertical cavity surface emitting laser (VCSEL).

The flat lens or the phase plate may provide arbitrary phase profile and may therefore be ideal for Gaussian beam transformation. Various embodiments may provide a methodology for the design, fabrication and characterization of flat lens or metalens for Gaussian beam transformations and may relate to the focusing and collimating functions for a single mode vertical cavity surface emitting laser (VCSEL).

A Gaussian beam is a beam of monochromatic electromagnetic radiation whose amplitude envelope in the transverse plane is given by a Gaussian function. As such, the Gaussian beam may have a Gaussian intensity (irradiance) profile. When a Gaussian beam is refocused by a lens (such as the lens structure as described herein), the transverse phase dependence is altered, resulting in a different Gaussian beam. In other words, the lens or lens structure may cause different phase shifts of the incoming Gaussian beam at different points of the lens or lens structure, thereby generating the outgoing Gaussian beam. An incoming Gaussian beam may also be referred to as an input Gaussian beam, and an outgoing Gaussian beam may also be referred to as an output Gaussian beam.

A flat lens may be a lens formed on a flat substrate. In a flat lens, focusing may be achieved by spatially arranging “zones” that impart different phase shifts of the incoming Gaussian beam (i.e. modify the phase distribution of the incoming Gaussian beam) to achieve constructive interference of the transmitted light or electromagnetic waves at the focus. On the other hand, a phase plate is a transparent plate that impart different phase shifts of the incoming Gaussian beam (i.e. modify the phase distribution of the incoming Gaussian beam) to achieve desired wave front or transformation of the transmitted light or electromagnetic waves.

In various embodiments, the lens structure 202 may include a plurality of unit elements. The lens structure 202 may also include such that the plurality of unit elements is in contact with the substrate. Each of the plurality of unit elements may be a nanostructure. Each of the plurality of unit elements has at least one dimension smaller than a wavelength of the incoming Gaussian beam.

In various embodiments, each of the plurality of unit elements may be any one selected from a group consisting of a pillar, a disk, a bar, a slot on the substrate, and a torus.

In various embodiments, each of the plurality of unit elements may have a cross-section or top surface of any one shape selected from a group consisting of a circle, an ellipse, a triangle, a square, an annular square, an annular ring, and a polygon.

In various embodiments, the plurality of unit elements may include any one material selected from a group consisting of amorphous silicon, titanium dioxide, aluminum oxide, hafnium oxide, niobium oxide, silicon nitride, gallium nitride, aluminum nitride, aluminum gallium nitride, gallium phosphide, aluminum phosphide, aluminum gallium phosphide, crystalline germanium and crystalline silicon.

In various embodiments, the outgoing Gaussian beam may be a converging beam.

In various other embodiments, the outgoing Gaussian beam may be a diverging beam.

In yet various other embodiments, the outgoing Gaussian beam may be a collimated beam.

In various embodiments, a ratio of a diameter of the lens structure to a radius of a beam waist of the incoming Gaussian beam may be any value equal to or greater than 2.

In various embodiments, the ratio of the diameter of the lens structure to the radius of the beam waist of the incoming Gaussian beam may be equal to 2, 2.5, π, 4.6 or greater.

The dimensions and a position of each of the plurality of unit elements may be based on a phase change required to be provided by each of the plurality of unit elements.

In various embodiments, the phase change required to be provided by each of the plurality of unit elements may be determined based on a radius of a curvature of the incoming Gaussian beam (Rᵢₙ) a desired distance between the lens structure and a beam waist of the outgoing Gaussian beam (f), a wavelength of the incoming Gaussian beam (λ), a desired beam radius of the incoming Gaussian beam at the lens structure (w), and a type of the outgoing Gaussian beam desired. Rᵢₙ and w may be derived from the input beam waist radius (w_{0,in}) and location (z) of the incoming Gaussian beam waist (relative to the lens).

In various embodiments, the incoming Gaussian beam and/or the outgoing Gaussian beam may be optical light. The incoming Gaussian beam and/or the outgoing Gaussian beam may, for instance, be infrared light (e.g. near or mid infrared light), visible light or ultraviolet light.

Various embodiments may relate to a lens structure configured to generate an outgoing Gaussian beam based on an incoming Gaussian beam.

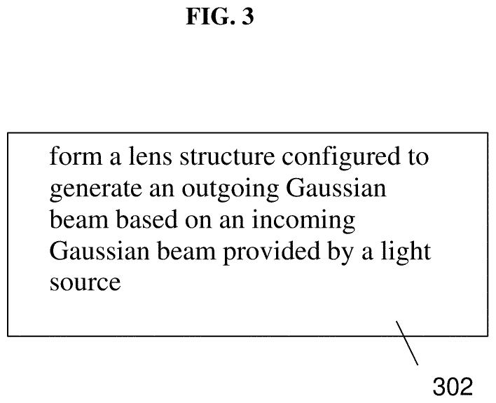

FIG. 3 is a general illustration of a method of forming an optical system according to various embodiments. The method may include, in 302, forming a lens structure configured to generate an outgoing Gaussian beam based on an incoming Gaussian beam provided by a light source. The lens structure may be a flat lens or a phase plate.

In other words, the method may include forming a lens structure such as a flat lens or a phase plate.

In various embodiments, the lens structure may include a plurality of unit elements. Forming the lens structure may include determining dimensions and a position of each of the plurality of unit elements based on a phase change required to be provided by each of the plurality of unit elements.

In various embodiments, the phase change required to be provided by each of the plurality of unit elements may be determined based on a radius of a curvature of the incoming Gaussian beam (Rᵢₙ) a desired distance between the lens structure and a beam waist of the outgoing Gaussian beam (f), a wavelength of the incoming Gaussian beam (λ), a desired beam radius of the incoming Gaussian beam at the lens structure (w), and a type of the outgoing Gaussian beam desired. Rᵢₙ and w may be derived from the input beam waist radius (w_{0,in}) and location (z) of the incoming Gaussian beam waist (relative to the lens).

The computation or determination of the phase change required to be provided by each of the plurality of unit elements may be carried out by a computer, a processor, or any circuit. In the current context, a “circuit” may be understood as any kind of a logic implementing entity, which may be special purpose circuitry or a processor executing software stored in a memory, firmware, or any combination thereof. Thus, in various embodiments, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail may also be understood as a “circuit” in accordance with various alternative embodiments. The computer, processor or circuit may include a software, program or application which may be configured to carry out the computation or the determination.

The type of the Gaussian beam may be any one selected from a diverging beam, a converging beam, and a collimated beam.

In various embodiments, forming the lens structure may include depositing a layer of lens material on a substrate, and forming the plurality of unit elements by patterning the layer of lens material.

In various embodiments, patterning the layer of lens material may include forming a patterned resist layer on the layer of lens materials, and etching the layer of lens material based on the patterned resist layer.

In various other embodiments, patterning the layer of lens material may include depositing a resist layer on a hard mask layer, patterning the resist layer to form a patterned resist layer, forming a hard mask based on the hard mask layer using the patterned resist layer, and etching the layer of lens materials based on the hard mask.

In various embodiments, each of the plurality of unit elements may have at least one dimension smaller than a wavelength of the incoming Gaussian beam.

In various embodiments, each of the plurality of unit elements may be any one selected from a group consisting of a pillar, a disk, a bar, a slot on the substrate, and a torus.

In various embodiments, each of the plurality of unit elements may have a cross-section of any one shape selected from a group consisting of a circle, an ellipse, a triangle, a square, an annular square, an annular ring, and a polygon.

In various embodiments, the plurality of unit elements may include any one material selected from a group consisting of amorphous silicon, titanium dioxide, aluminum oxide, hafnium oxide, niobium oxide, silicon nitride, gallium nitride, aluminum nitride, aluminum gallium nitride, gallium phosphide, aluminum phosphide, aluminum gallium phosphide, crystalline germanium, and crystalline silicon.

In various embodiments, a ratio of a diameter of the lens structure to a radius of a beam waist of the incoming Gaussian beam may be any value equal to or greater than 2. The ratio of the diameter of the lens structure to the radius of the beam waist of the incoming Gaussian beam may be equal to 2, 2.5, π, 4.6, or greater.

Various embodiments may relate to a method of forming a lens structure.

Various embodiments may relate to a method of generating an outgoing Gaussian beam from an incoming Gaussian beam using an optical system according to various embodiments. The method may include providing the incoming Gaussian beam to a lens structure such that the lens structure generates the outgoing Gaussian beam based on the incoming Gaussian beam. The lens structure may be a flat lens or a phase plate. The method may also include forming the lens structure before providing the incoming Gaussian beam to the lens structure. The method may also include determining or computing a phase change required to be provided by each of a plurality of unit elements of the lens structure before forming the lens structure (e.g. forming the plurality of unit elements on a substrate).

Various embodiments may relate to computer-readable medium storing computer executable code, including instructions for computing or determining the phase change required to be provided by each of the plurality of unit elements of the lens structure.

A design methodology for Gaussian beam transformation may be described herein. The electromagnetic field of a fundamental Gaussian beam can be expressed as follows:

$$E ( r , z ) = {E}_{0} \frac{{w}_{0}}{w ( z )} {e}^{\frac{- {r}^{2}}{{e}^{{w ( z )}^{2}}}} {e}^{- i ( k z + k \frac{{r}^{2}}{2 R ( z )} - ψ ( z ) )} \qquad ( 1 )$$

where r is the radial distance from the center axis of the beam, z is the distance from the beam waist, k=2π/λ is the wave number and λ is the wavelength, E₀ is the electric field amplitude at the center of the beam waist, w(z) is the radius of the beam at position z where the field amplitude falls to 1/e of the center value, w₀ is the beam waist radius, R(z) is the radius of curvature of the beam's wave front at z, and ψ(z) is the Gouy phase at z.

The radius of the beam at position z, w(z) may be defined as:

$$w ( z ) = {w}_{0} \sqrt{1 + {( \frac{z}{{z}_{R}} )}^{2}} \qquad ( 2 )$$

where z_{R} is the Rayleigh range and is provided by:

$${z}_{R} = \frac{π {w}_{0}^{2}}{λ} \qquad ( 3 )$$

R(z), the radius of curvature of the wave front of the beam at z may be defined by:

$$R ( z ) = z [ 1 + {( \frac{{z}_{R}}{z} )}^{2} ] \qquad ( 4 )$$

The Gouy phase ψ(z) may be defined by:

$$ψ ( z ) = arctan ( \frac{z}{{z}_{R}} ) \qquad ( 5 )$$

The amplitude distribution of a Gaussian beam at any cross-section perpendicular to the beam propagation direction may be a Gaussian distribution, so the phase profile in the cross section may completely determine the Gaussian beam. A flat lens or a phase plate may be used to modify the phase distribution of a Gaussian beam to convert it to another one.

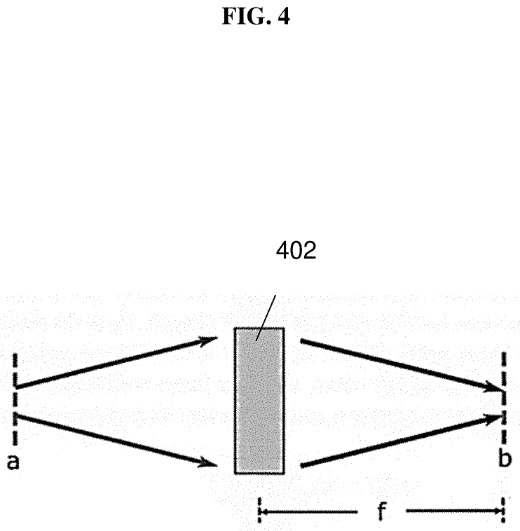

FIG. 4 is a schematic illustrating the transformation of an input Gaussian beam to an output Gaussian beam by a flat lens or a phase plate 402 according to various embodiments.

The input Gaussian beam has the beam waist at position a, and the output Gaussian beam waist is at position b. The distance between the flat lens or the phase plate 402 and the output waist at b is f Both sides of the flat lens or the phase plate 402 are air.

The phase change induced by the lens or phase plate therefore should be:

$$ϕ ( r ) = \frac{{π r}^{2}}{λ} ( \frac{1}{{R}_{in}} + \frac{1}{{R}_{o u t}} ) \qquad ( 6 )$$

where Rᵢₙ and Rₒᵤₜ are the radii of the curvature of the input and output Gaussian beams respectively, and r is the radial distance from the center axis of the beam. Rᵢₙ may be determined by the input beam, while Rₒᵤₜ may be dependent on the output beam desired. If the distance between the flat lens or phase plate and the output beam waist is f the output beam waist radius w_{0,out} may be provided by:

$${w}_{0 , out}^{2} = \frac{{w}^{2} \pm \sqrt{{w}^{4} - 4 {f}^{2} {λ}^{2} / {π}^{2}}}{2} \qquad ( 7 )$$

where w is the beam radius at the flat lens or the phase plate. The radius of curvature of the output beam can be calculated by:

$${R}_{o u t} = f [ 1 + {( \frac{{z}_{R , o u t}}{f} )}^{2} ] \qquad ( 8 )$$

where z_{R,out} is the Rayleigh range of the output beam defined by:

$${z}_{R , o u t} = \frac{π {w}_{0 , out}^{2}}{λ} \qquad ( 9 )$$

In the above solution, the flat lens or the phase plate 402 are assumed to be in air, so the refractive index on both sides of the flat lens or the phase plate 402 are taken to be 1. If the input medium and/or the output medium are different, the above equations may need to be modified.

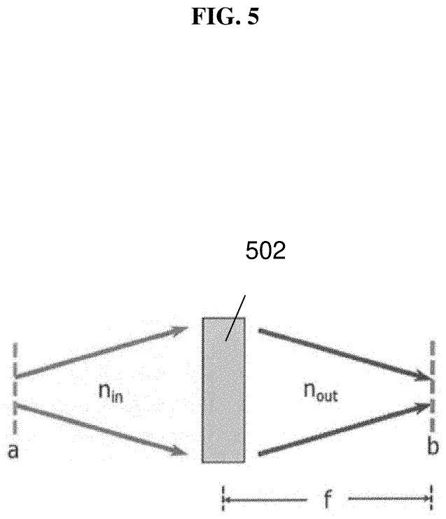

FIG. 5 is a schematic illustrating the transformation of an input Gaussian beam to an output Gaussian beam by a flat lens or a phase plate 502 in which the input medium is of refractive index nᵢₙ and the output medium is of refractive index nₒᵤₜ according to various embodiments. The input beam waist is at position a and the output beam waist is at position b. The distance between the flat lens or the phase plate and output beam waist at b is f. The input medium has refractive index nᵢₙ, and the output medium has the refractive index nₒᵤₜ.

If the input medium and output medium are not air, as shown in FIG. 5, equation (6) is rewritten as:

$$ϕ ( r ) = \frac{{π r}^{2}}{λ} ( \frac{{n}_{in}}{{R}_{in}} + \frac{{n}_{o u t}}{{R}_{o u t}} ) \qquad ( 10 )$$

The output beam waist radius may then be provided by:

$${w}_{0 , out}^{2} = \frac{{w}^{2} \pm \sqrt{{w}^{4} - 4 {f}^{2} {λ}^{2} / {n}_{o u t}^{2} {π}^{2}}}{2} \qquad ( 11 )$$

The Rayleigh range of the output beam may be provided by:

$${z}_{R , o u t} = \frac{π {n}_{o u t} {w}_{0 , o u t}^{2}}{λ} \qquad ( 12 )$$

In FIGS. 4 and 5, the input beam waist is illustrated at the left side of the flat lens or the phase plate and the output beam waist is at the right side of the flat lens or the phase plate. In situations opposite to this (i.e. the input beam waist is at the right side of the flat lens or the phase plate and the output beam waist is at the left side of the flat lens or the phase plate), a “−” sign is required for Rᵢₙ and/or Rₒᵤₜ.

In addition, for a specified f, the output waist size may have 2 solutions according to Equations (7) and (11) with “+” or “−” signs. The solution with the “+” sign may provide a large beam waist, and may be suitable for beam collimation. On the other hand, the solution with the “−” sign may give a small beam waist, and may be good for beam focusing. For beam collimation, the largest possible beam waist may occur at f=0, which means that the beam waist is at the flat lens or a phase plate location, so the largest beam waist is simply the beam size at the flat lens or a phase plate, i.e.

w_{0,out}=w (13)

Various embodiments may relate to the determination or calculation of the phase change required to be provided by each of the plurality of unit elements. In various embodiments, the refractive index of the input medium nᵢₙ and the refractive index of the output medium nₒᵤₜ may be known. In various embodiments, the phase change required to be provided by each of the plurality of unit elements may be determined based on a radius of a curvature of the incoming Gaussian beam (Rᵢₙ) (which in turn is determined by the input beam waist radius (w_{0,in}) and location (z) of the incoming Gaussian beam waist (relative to the lens)), a desired distance between the lens structure and a beam waist of the outgoing Gaussian beam (f), a wavelength of the incoming Gaussian beam (λ), and a type of the outgoing Gaussian beam desired. Referring to Equation (10), Rᵢₙ, Rₒᵤₜ and λ may be required for the determination or calculation of the phase change required to be provided by each of the plurality of unit elements (ϕ(r)). Rₒᵤₜ may be determined or computed from z_{R,out} and f (see Equation (8)), while z_{R,out} may be determined by λ and w_{0,out}² (see Equation (11)). Referring to Equation (11), w_{0,out}² may be determined by the type of the outgoing Gaussian beam desired (which determines the sign “+” or “−” in Equation (11), w, f as well as λ. w (i.e. the beam radius at the flat lens or the phase plate) may be derived from Equation (2) based on the input beam waist radius (w_{0,in}) and location (z) of the incoming Gaussian beam waist (relative to the lens). On the other hand, Rᵢₙ may be determined by the input beam waist radius (w_{0,in}) and location z of the incoming Gaussian beam waist (relative to the lens) (see Equations (2) and (3)). The lens structure (e.g. a flat lens or a phase plate) may be designed and subsequently fabricated after ϕ(r) at various r is known. As such, the lens structure may be designed and fabricated without need for numerical simulation of the mode profile of individual laser cavity.

The flat lens or the phase plate may be made of nanostructures that can control the polarization, phase, and amplitude of light waves locally, and may provide arbitrary phase distribution profiles. As such, the flat lens or the phase plate may have significant advantages over the traditional bulky lenses and may be suitable for transformation of Gaussian beams. Various embodiments may relate to the use of the flat lens or the phase plate to modify the phase distribution of an incoming Gaussian beam to convert the incoming Gaussian beam to an outgoing Gaussian beam.

The nanostructures or sub-wavelength structures may be fabricated on a substrate that is transparent to the optical light of interest, such as glass, quartz, sapphire for visible to near infrared (IR) light, or magnesium fluoride (MgF₂) for mid-IR light. The nanostructures or sub-wavelength structures that are used to modify the phase distribution of the Gaussian beams may be in shape of pillars, disks, bars, or slits arranged according to the design, and may be made of low loss materials with refractive index higher than the substrate.

The nanostructures or sub-wavelength structures may be titanium dioxide (TiO₂), silicon nitride (SiₓN_{y}), aluminum gallium nitride (GaAlN), aluminum gallium phosphide (GaAlP) for visible light, or crystalline silicon (Si), amorphous Si (a-Si), crystalline germanium (Ge), titanium dioxide (TiO₂), silicon nitride (SiₓN_{y}), aluminum gallium nitride (GaAlN), gallium aluminum phosphide (GaAlP) for near IR and above.

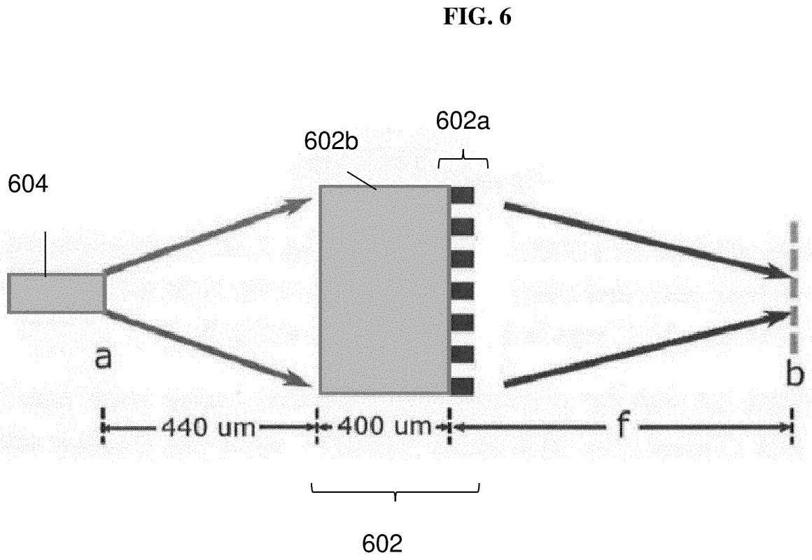

Flat lenses that transform a Gaussian beam emitted from a vertical cavity surface emitting laser (VCSEL) to other Gaussian beams have been designed, fabricated and tested. FIG. 6 is a schematic showing an optical system according to various embodiments. The optical system may include a lens structure 602 including a plurality of unit elements or nanostructures 602a, as well as a glass substrate 602b such that the plurality of unit elements or nanostructures 602a is in contact with the substrate 602b. The incoming Gaussian beam is emitted by the VCSEL 604 may be a single mode Gaussian beam with a wavelength of 940 nm and a beam waist of 2.5 μm. The glass substrate 602b may have a thickness of about 400 μm, and the distance between the glass substrate 602b and the VCSEL 604 may be 440 μm. In this configuration, the beam waist or size at the lens structures 602 is 171 μm (defined by the diameter where the field amplitude at the edge is 1/e of the center) while the lens structures 602 has a diameter of 393 μm, which is about 2.3 times of the beam waist diameter or size, or 4.6 w, to cover practically all the energy of the incident beam (i.e. 393/171=2.3). Other lens diameter values such as 2 w, 2.5 w or πw may also be used, depending on the application scenario.

4 different flat lenses may be used to achieve different outputs. The beam waist locations of the 4 designs are listed in Table 1.

TABLE 1
Flat lenses designed and tested. f is the distance between the
flat lens and the output beam waist; the corresponding beam
waist sizes and the half divergence angles are also listed.

| | Beam Waist | Divergence |
|---|---|---|
| f (μm) | Diameter Size (μm) | Angle (Half) |
| 200 | 1.4 | 24.5° |
| 500 | 3.5 | 9.8° |
| 1000 | 7 | 4.9° |
| 0 | 171 | 0.2° |

In the 4 designs, the “−” sign solution in Equation (11) may be used for the 3 designs with f=200 μm, 500 μm and 1000 μm, so these lenses may work like focusing lenses and may provide a small output beam waist. For f=0 the “+” sign solution may be used, so this lens may work like a collimating lens and may provide the largest beam waist of 171 and the smallest divergence angle of 0.2°. f may be varied by changing the dimensions and/or the positions of the unit elements of the nanostructures. Depending on f, the beam waist of the outgoing Gaussian beam may be changed.

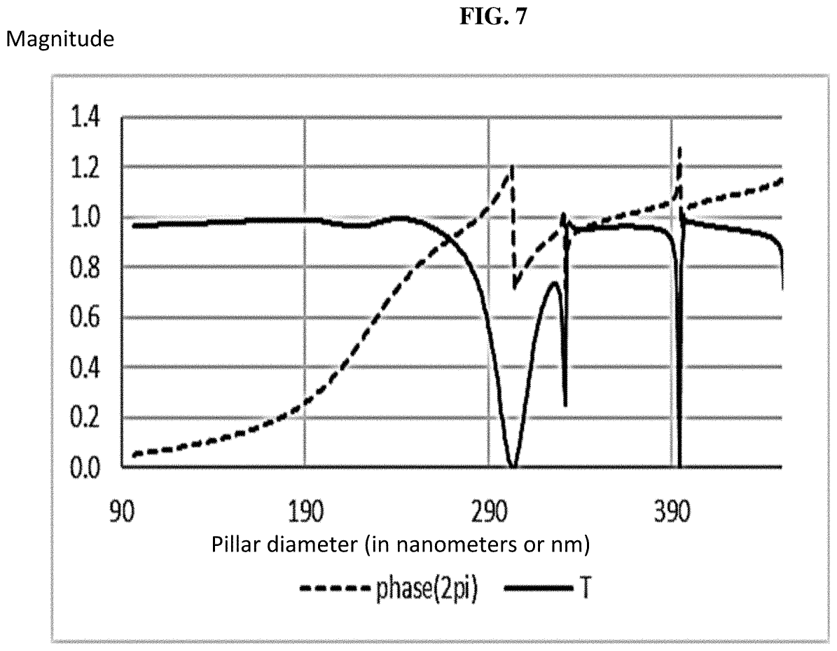

Amorphous silicon (a-Si) circular pillars may be used to form the flat lenses. The pillars are circular, so that the lenses made of the pillars may work with any polarization (i.e. the lens structures are polarization insensitive). FIG. 7 shows a plot of magnitude as a function of pillar diameter (in nanometers or nm) illustrating the phase change and transmission of an array of circular pillars with different diameters according to various embodiments. The unit for the phase change is 2π. The height of the pillars is 485 nm, and the gap between pillars is set to 190 nm. A pillar diameter range of 139-434 nm has been selected to cover 2π phase shift while keeping the transmission over 0.8.

A full wave simulation of both focusing lens and collimating lens has also been run. Due to the limitation of computer resources, a lens diameter (D) of 4.6 w (i.e. 147 μm) is chosen. Other input parameters include an input beam waist of 2.5 μm, a distance between the beam waist and the flat lens of 389 μm (in glass), and an input Gaussian beam diameter of 64 μm.

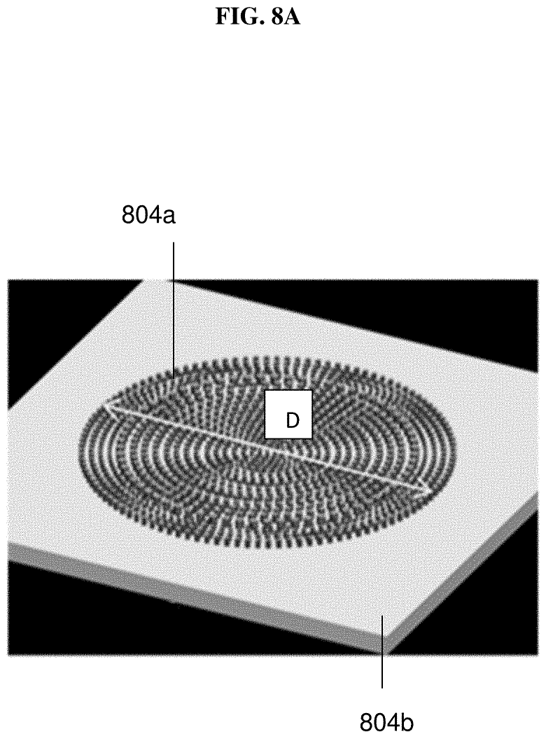

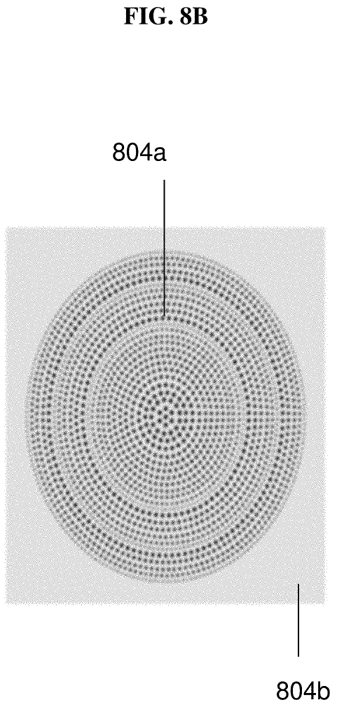

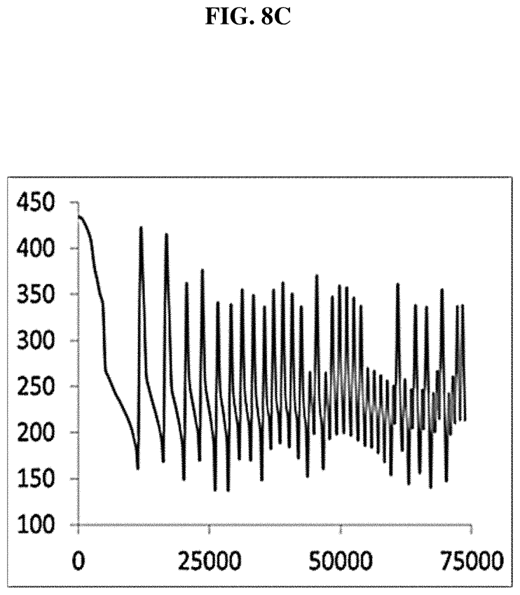

FIG. 8A shows a perspective view of a full lens structure including a plurality of pillars 804a and a glass substrate 804b according to various embodiments. FIG. 8B shows a top view of a full lens structure as shown in FIG. 8A according to various embodiments. FIG. 8C shows a plot of pillar diameter (in nanometers or nm) as a function of ring radius (in micrometers or μm) showing the distribution of pillar diameters across the ring radius of a lens according to various embodiments. The lens may have D=147 μm, f=100 μm.

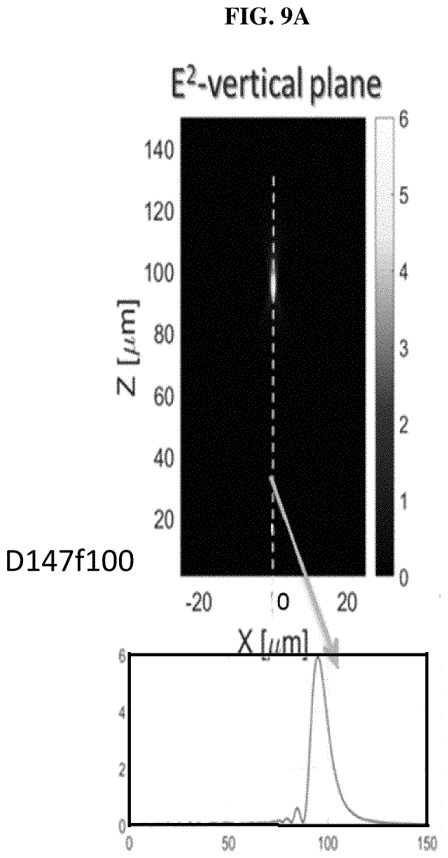

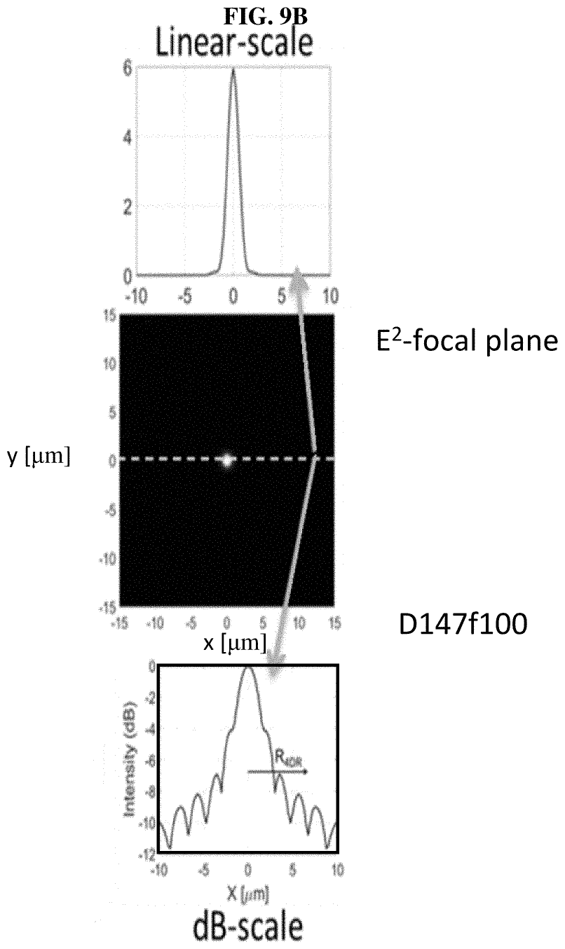

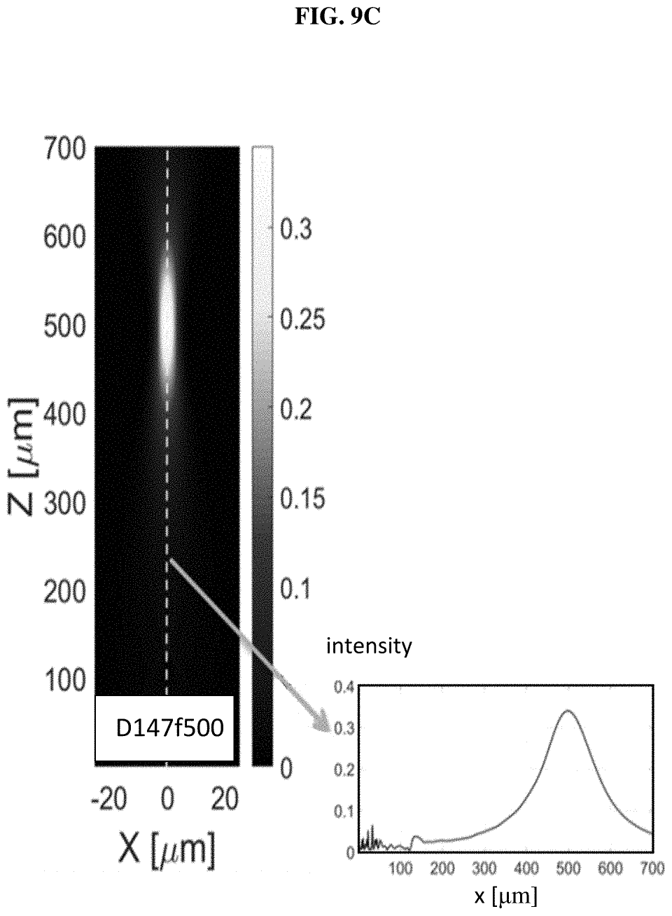

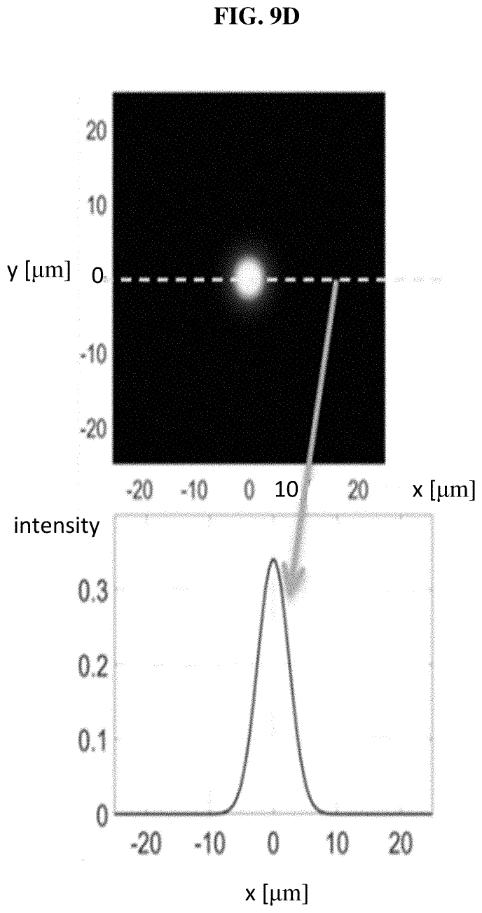

In order to benchmark the theoretical results, the full lens with the Gaussian beam input may be simulated. The field intensities along xz cross section from near the lens surface to several hundred micrometers (beyond the proposed focusing distance) as well as along the xy cross section are captured and shown in FIGS. 9A-B for f=100 μm and FIGS. 9C-D for f=500 μm.

FIG. 9A shows (above) the field intensity along the xz cross section generated by an optical system according to various embodiments; and (below) a plot of intensity as a function of distance along the z direction (in micrometers or μm) illustrating the variation of intensity along the dashed line shown according to various embodiments.

FIG. 9B shows (middle) the field intensity along the xy cross section generated by the optical system according to various embodiments; (top) a linear scale plot of intensity as a function of distance along the x direction (in micrometers or μm) illustrating the variation of intensity along the dashed line according to various embodiments; and (bottom) a plot of intensity (in decibels or dB) as a function of distance along the x direction (in micrometers or μm) illustrating the variation of intensity along the dashed line according to various embodiments

FIG. 9C shows (left) the field intensity along the xz cross section generated by another optical system according to various embodiments; and (right) a plot of intensity as a function of distance along the z direction (in micrometers or μm) illustrating the variation of intensity along the dashed line shown according to various embodiments.

FIG. 9D shows (top) the field intensity along the xz cross section generated by another optical system according to various embodiments; and (bottom) a plot of intensity as a function of distance along the z direction (in micrometers or μm) illustrating the variation of intensity along the dashed line shown according to various embodiments.

From these results, the focal distance where the maximum intensity along z-axis occurs may be calculated. FIG. 9B illustrates the intensity at the focusing plane (E²-focal plane), which proportionally represents how well the focusing lens is performing. The focusing efficiency may be defined as the fraction of the incident light that passes through a circular aperture in the focal plane with a radius equal to four dark rings captured at the beam waist spot area (as shown in bottom of FIG. 9B in dB-scale). FIGS. 9A-D confirm that the flat lenses according to various embodiments are theoretically and numerically consistent.

The results of focusing lenses are summarized in the Table 2 with respect to 2 lenses having different focal distances (f) with the same diameter D=147 μm.

TABLE 2
Different parameters of Gaussian beam focusing
lenses based on the full lens simulation

| | Lens with f = 100 μm | Lens with f = 500 μm |
|---|---|---|
| Gaussian beam | (D147f100) | (D147f500) |
| Foci (f) | 96 μm | 498 μm |
| Beam Waist_{Theory} | 1.9 μm | 9.5 μm |
| Beam Waist_{SIM} | 2.1 μm | 9.5 μm |
| Transmittance | 90% | 93% |
| Focusing Efficiency | 87% | 89% |

The numerical simulation results agree with the theoretical prediction ones for both the focal distance/foci and beam waist (measured at 1/e²). Moreover, it may be observed that these lenses exhibit very high transmission efficiency (>90%) and focusing efficiency (nearly 90%).

It has also been demonstrated that the lens design based on the conventional method for the plane wave may not apply to Gaussian beams. A full lens for both plane wave and Gaussian beam inputs is simulated, with the full lens diameter being 20 μm, the focal distance being 20 μm (NA˜0.45), and the wavelength being 940 nm. Amorphous silicon pillars are formed with gaps of 210 nm and heights of 505 nm on the quartz substrate. The full lens simulation results for both plane wave and Gaussian beam excitation.

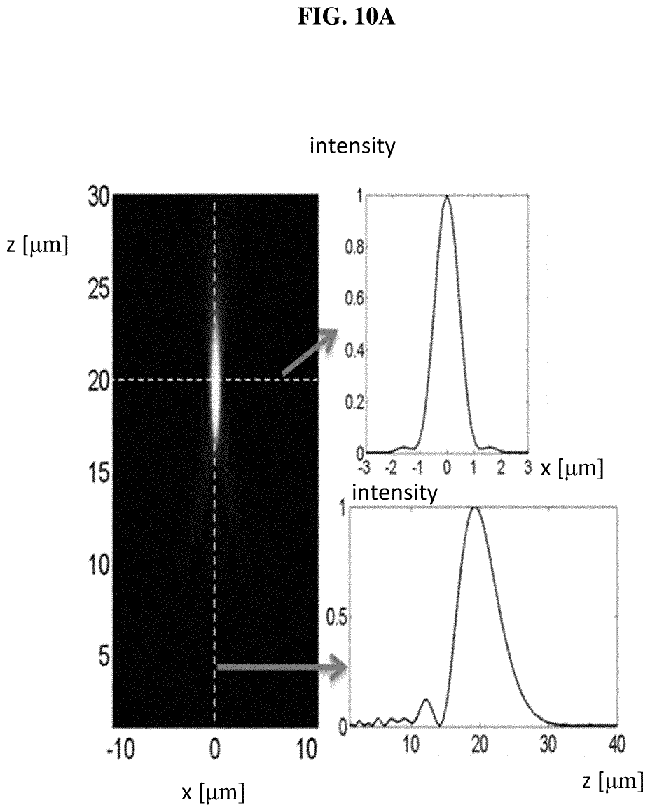

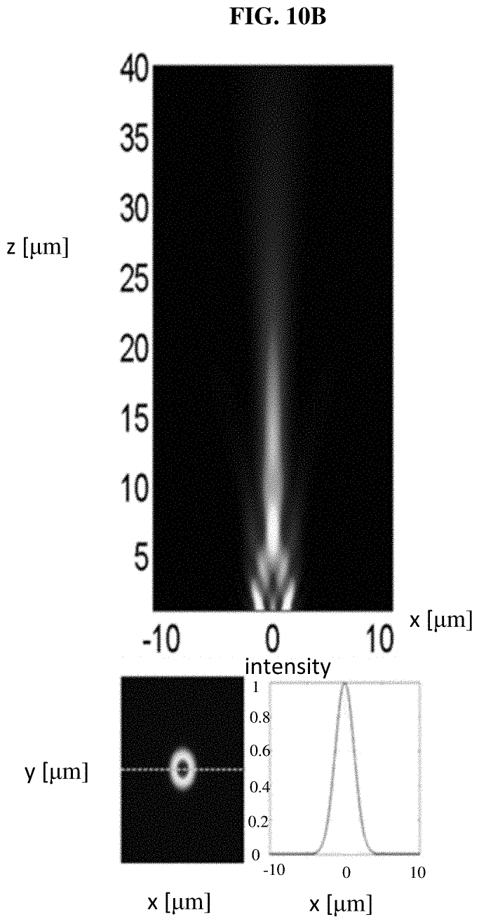

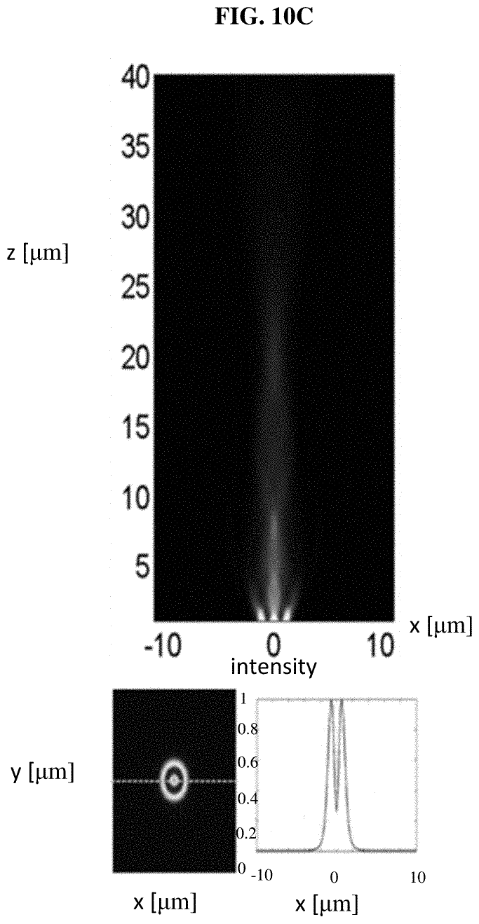

FIG. 10A shows (left) the field intensity along the xz cross section generated by full lens simulation based on plane wave excitation; (top right) a plot of intensity as a function of distance along the x direction (in micrometers or μm) illustrating the variation of intensity along the horizontal dashed line shown; and (bottom right) a plot of intensity as a function of distance along the z direction (in micrometers or μm) illustrating the variation of intensity along the vertical dashed line shown.

FIG. 10B shows (top) the field intensity along the xz cross section generated based on a Gaussian beam excitation; (bottom left) the field intensity along the xy cross section generated based on the Gaussian beam excitation; and (bottom right) a plot of intensity as a function of distance along the x direction (in micrometers or μm) illustrating the variation of intensity along the x direction.

FIG. 10C shows (top) the field intensity along the xz cross section generated based on another Gaussian beam excitation; (bottom left) the field intensity along the xy cross section generated based on the Gaussian beam excitation; and (bottom right) a plot of intensity as a function of distance along the x direction (in micrometers or μm) illustrating the variation of intensity along the x direction.

FIG. 10A shows that the lens designed for plane wave is able to focus the plane wave well as expected. In contrast, the lens does not perform satisfactorily when Gaussian beams are used, as shown in FIGS. 10B-C. The result shows that for practical application of flat lens on Gaussian beam based light sources such as laser or VCSEL, the proposed method as described herein may be required to implement the proper design.

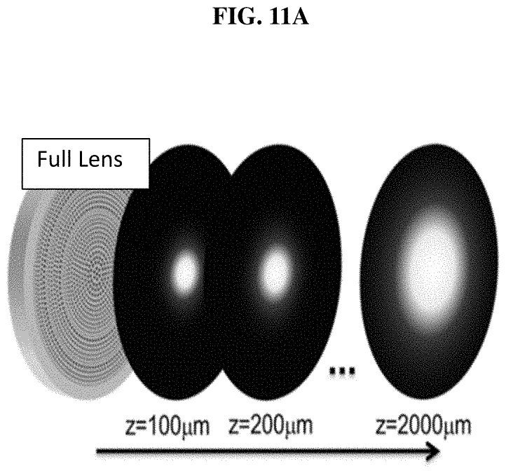

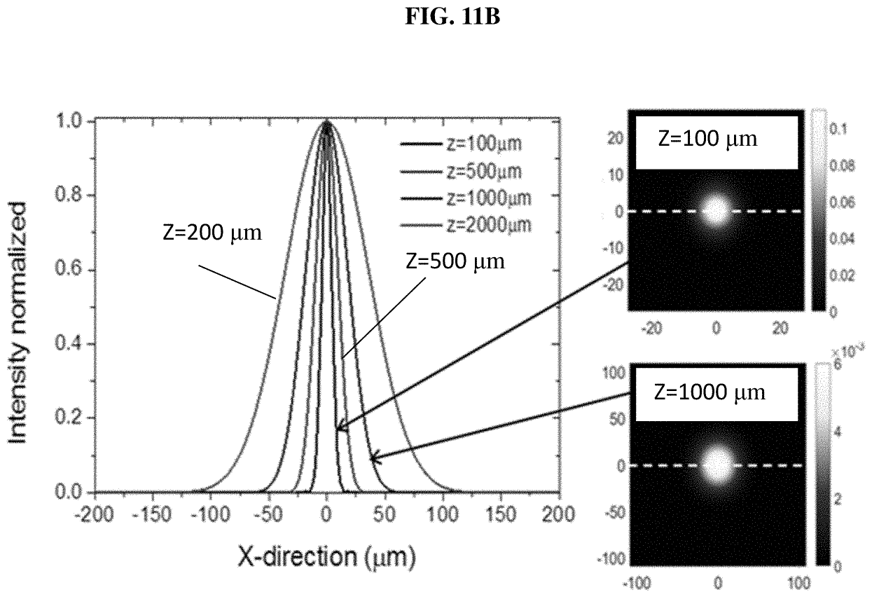

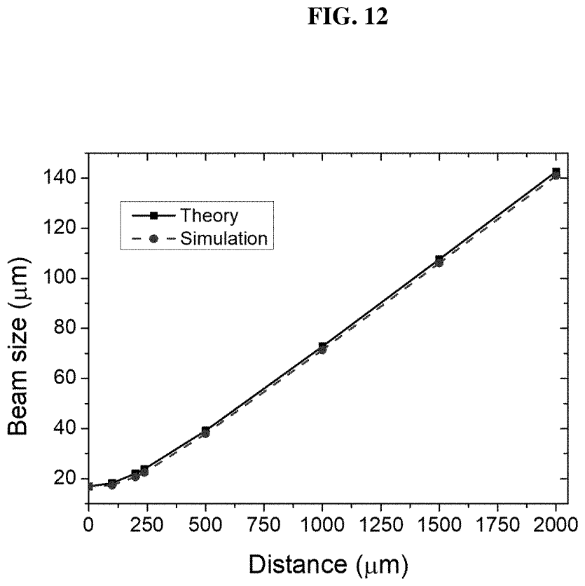

The proposed methodology may also be used for collimating lenses. The parameters used for the full lens simulation are: beam waist 2.5 μm, beam waist location 98.4 μm (in glass), input Gaussian beam size 16.9 μm, lens diameter 39 μm, a-Si pillars height 485 nm and gap between pillars 190 nm. The sizes of the Gaussian beam at several distances after the lens are calculated to predict the divergent angle of the collimating lens. FIG. 11A shows a schematic of a collimating lens and the intensities of the outgoing Gaussian beam from the collimating lens at several points according to various embodiments. FIG. 11B shows a plot of normalized intensity as a function of distance along the x-direction (in micrometer or μm) of the full lens simulations of the lens shown in FIG. 11A according to various embodiments. The results of the full lens simulation may be compared with theoretical prediction. The beam size extracted from full lens simulation results is compared with the ones predicted by the theory. FIG. 12 shows a plot of beam size (in micrometer or μm) as a function of distance (in micrometer or μm) comparing theoretical calculation and full lens simulation of beam sizes captured at different distances when a Gaussian beam passes through the collimating lens according to various embodiments. The divergence angle derived from the beam size results may approximately be ˜4°, which matches the theoretical calculation perfectly.

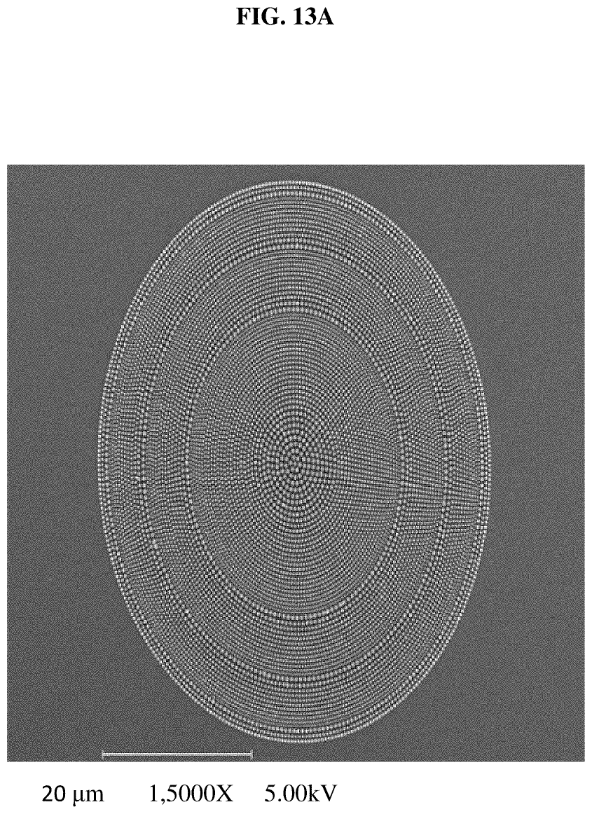

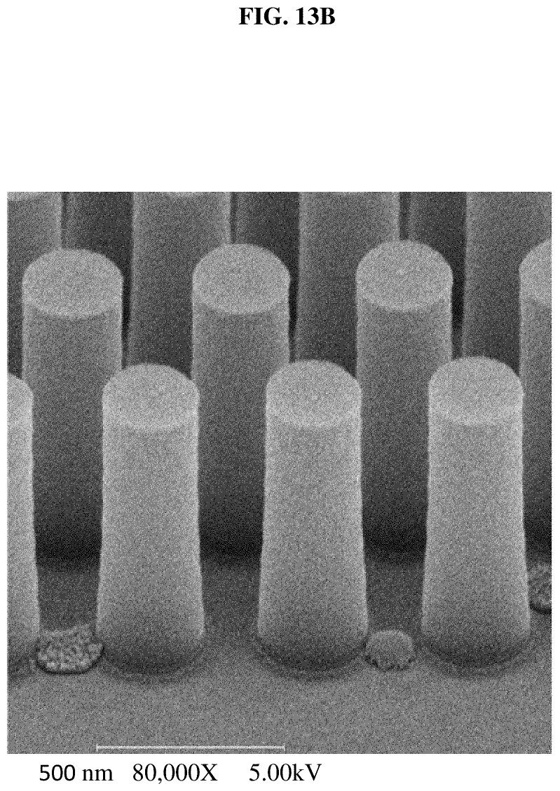

The flat lens for both Gaussian beam focusing and collimation are fabricated for experimental demonstration. Amorphous silicon (a-Si) is deposited by inductively coupled plasma chemical vapor deposition (ICP-CVD). Electron beam lithography (EBL) is used to pattern the flat lens structure in hydrogen silsesquioxane (HSQ) resist and then transferred to a thin layer of chromium (Cr) as hard mask. The flat lens is formed after a-Si pillar plasma etching and removal of the masking layer. FIG. 13A is a scanning electron microscopy (SEM) image showing a top view of a fabricated flat lens according to various embodiments. FIG. 13B is another scanning electron microscopy (SEM) image showing a tilted, magnified view of FIG. 13A according to various embodiments. FIG. 13B shows details of the individual pillars.

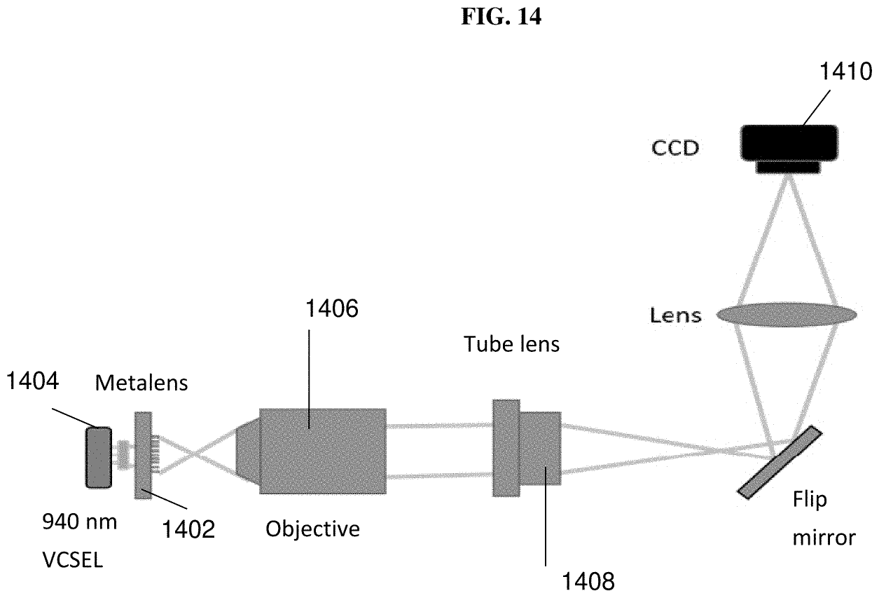

The fabricated lens was tested using an optical testing set up showed in FIG. 14. FIG. 14 is a schematic showing an optical testing step up or optical system according to various embodiments. The optical system may include a flat lens 1402 (alternatively referred to as metalens) and a VCSEL 1404 emitting at wavelength of 940 nm as the illuminating light source. The optical system or set up may also include an 50× objective lens 1406 together with a tube lens 1408 and a camera 1410 (e.g. charge-coupled device or CCD) used to collect the cross section image of the laser beam after the flat lens 1402 (i.e. the outgoing Gaussian beam generated). The optical system may also include a flip mirror 1412 and a lens 1414 to direct the outgoing laser beam from the tube lens 1408 to the camera 1410.

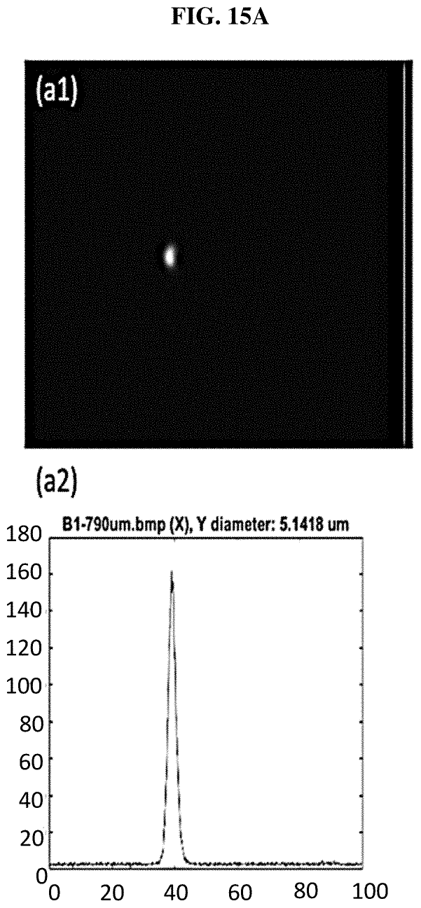

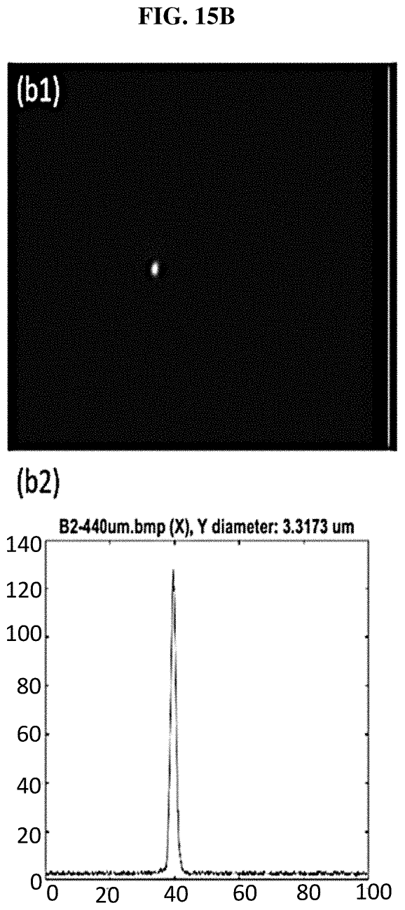

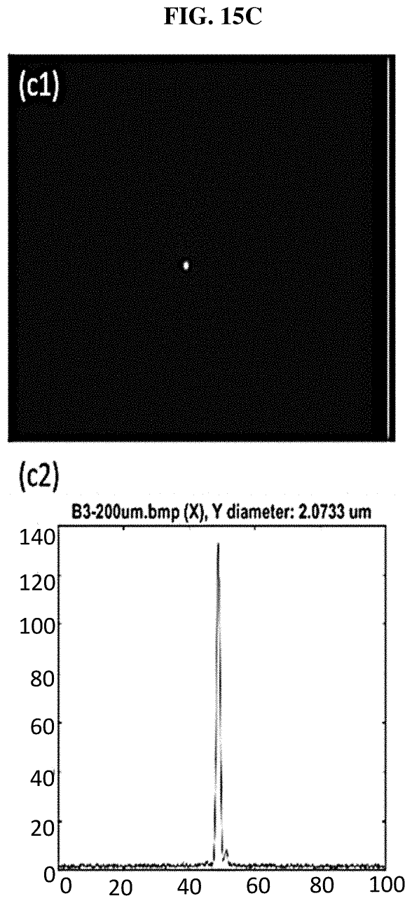

Based on the magnification of the lens system and the pixel size of the camera, the exact value of the beam diameter may be obtained. FIGS. 15A-C illustrate the optical images of the Gaussian beam waist captured by a camera for 3 flat lenses with different focal lengths and their corresponding x-cut line profiles. FIG. 15A shows (top) the image of the Gaussian beam after passing through the 393 μm focusing flat lens with a focal length (f) of 1000 μm according to various embodiments; and (bottom) a plot of intensity as a function of distance (in micrometers or μm) illustrating the x-cut line profile of the Gaussian beam shown according to various embodiments. FIG. 15B shows (top) the image of the Gaussian beam after passing through the 393 μm focusing flat lens with a focal length (f) of 500 μm according to various embodiments; and (bottom) a plot of intensity as a function of distance (in micrometers or μm) illustrating the x-cut line profile of the Gaussian beam shown according to various embodiments. FIG. 15C shows (top) the image of the Gaussian beam after passing through the 393 μm focusing flat lens with a focal length (f) of 200 μm according to various embodiments; and (bottom) a plot of intensity as a function of distance (in micrometers or μm) illustrating the x-cut line profile of the Gaussian beam shown according to various embodiments.

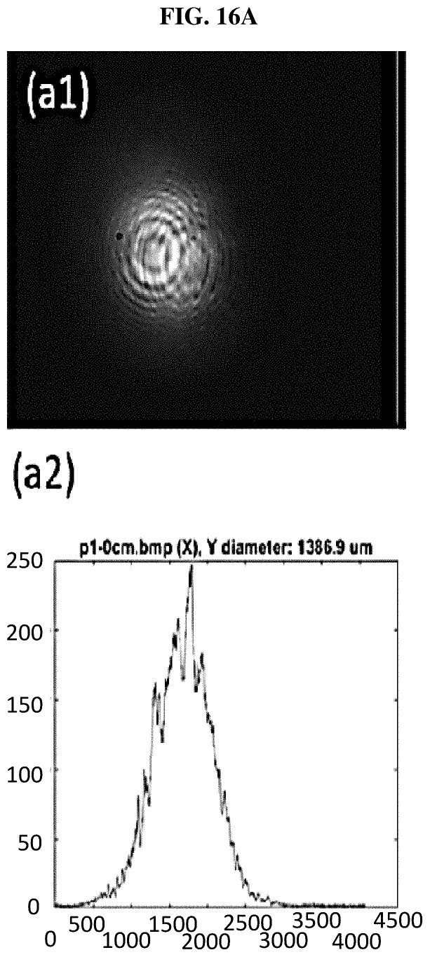

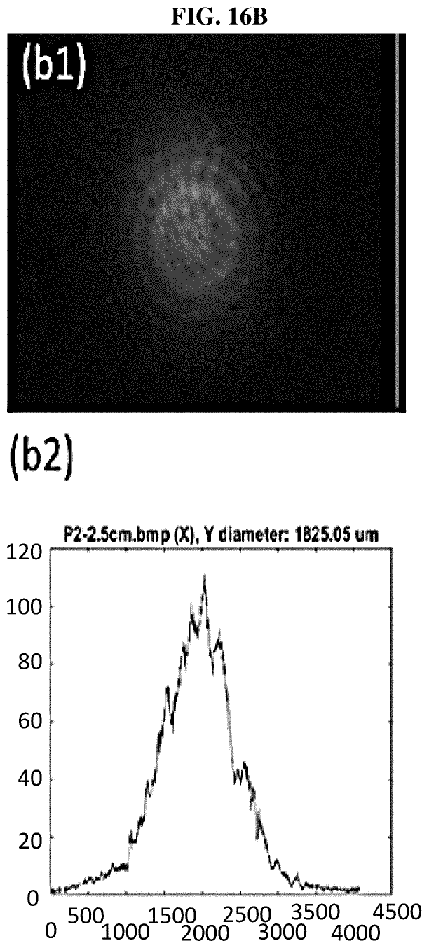

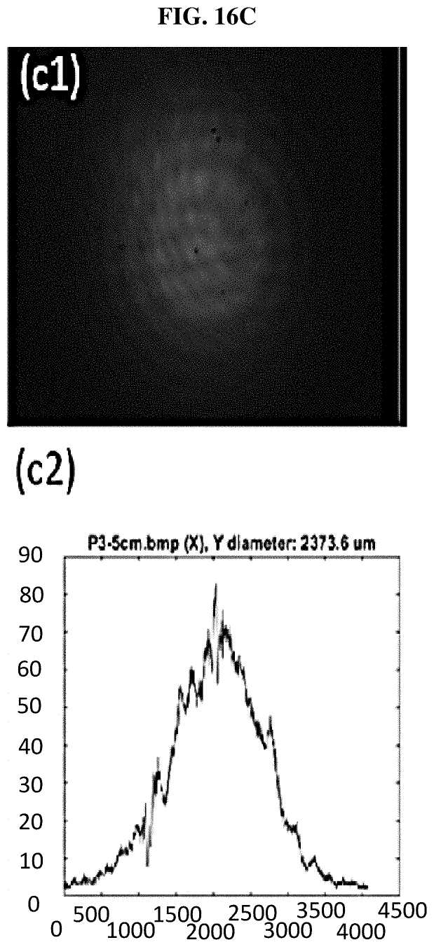

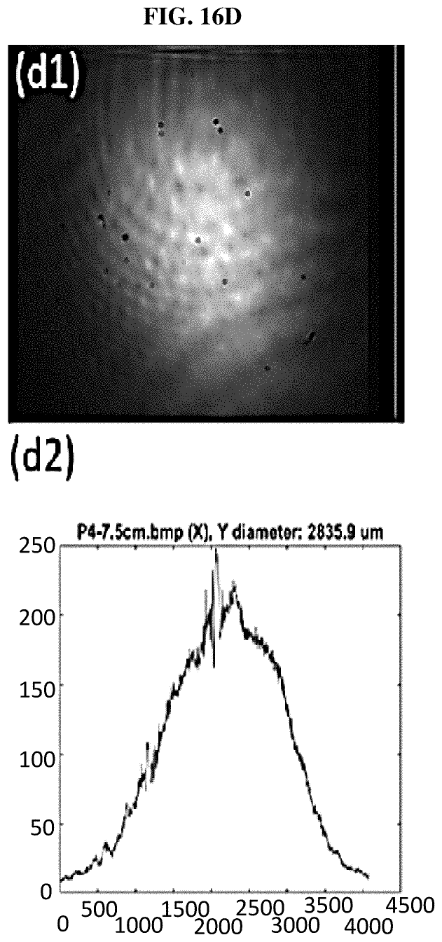

The measured beam waist diameter and the position match relatively well with the design. FIGS. 16A-D show the images of the Gaussian beam and their corresponding x-cut beam profiles captured by the camera at different z positions along the propagation direction after a collimating flat lens.

FIG. 16A shows (top) the image of the Gaussian beam after passing through the collimating lens at z position=0 (which is an arbitrary position) according to various embodiments; and (bottom) a plot of intensity as a function of distance (in micrometers or μm) illustrating the x-cut line profile of the Gaussian beam shown according to various embodiments. FIG. 16B shows (top) the image of the Gaussian beam after passing through the collimating lens at z position=2.5 cm according to various embodiments; and (bottom) a plot of intensity as a function of distance (in micrometers or μm) illustrating the x-cut line profile of the Gaussian beam shown according to various embodiments. FIG. 16C shows (top) the image of the Gaussian beam after passing through the collimating lens at z position=5 cm according to various embodiments; and (bottom) a plot of intensity as a function of distance (in micrometers or μm) illustrating the x-cut line profile of the Gaussian beam shown according to various embodiments. FIG. 16D shows (top) the image of the Gaussian beam after passing through the collimating lens at z position=7.5 cm according to various embodiments; and (bottom) a plot of intensity as a function of distance (in micrometers or μm) illustrating the x-cut line profile of the Gaussian beam shown according to various embodiments.

The data is summarized in Table 3.

TABLE 3
Beam width and divergence angle of the Gaussian
beam after the collimating flat lens

| | Beam | Beam | Diverging |
|---|---|---|---|
| Position | width_X | width_Y | angle_X |
| (cm) | (μm) | (μm) | (degree) |
| 0 | 1386.90 | 1555.95 | |
| 2.5 | 1825.05 | 2228.70 | 1.00 |
| 5 | 2373.60 | 3011.85 | 1.26 |
| 7.5 | 2835.90 | 3456.90 | 1.08 |
| | | Average | 1.11 |

The average divergence angle in measurement is about 1.1°. Comparing with the original Gaussian beam diverging angle of 13.6°, the Gaussian beam collimating flat lens has been shown to be effective in collimating the Gaussian beam.

Various embodiments may relate to a methodology to design and fabricate a flat lens or a phase plate for Gaussian beam or laser beam transformation, in which the phase profile of the flat lens or the phase plate can be designed according to a set of formulas that only need input of the incoming Gaussian beam diameter and the application requirement, without the need for numerical simulation of the mode profile of individual laser cavity.

Various embodiments may relate to a methodology to design and fabricate a flat lens or a phase plate for Gaussian beam or laser beam transformation, in which the wave front after the flat lens or the phase plate can be a focused Gaussian beam with a smaller beam waist, or a diverging Gaussian beam with larger beam waist, or a collimated Gaussian beam with a small diverging angle, or other type of wave fronts.

Various embodiments may relate to a methodology to design and fabricate a flat lens or a phase plate for Gaussian beam or laser beam transformation, in which size of the flat lens or the phase plate can be set according the requirement and application scenario, to be from 2 times beam waist radius, to 2.5 times, 3.14 times, 4.6 times or larger.

Various embodiments may relate to a methodology to design and fabricate a flat lens or a phase plate for Gaussian beam or laser beam transformation, in which an array of a-Si pillars can be used to form the flat lens or the phase plate and the a-Si pillars can be fabricated through a series of semiconductor processing with required profile in terms of diameter, height, side wall, smoothness and uniformity. The shape of the constructing unit cell may not be limited to pillars. The shapes may be other shapes like disks, bars, triangles/squares/multi-polygons, slots, annular rings, etc. The diameter of the unit cell and the pitch of the array may be smaller the wavelength of the Gaussian beam or laser beam. The materials for the unit cell may not be limited to a-Si, they can be TiO₂, Al₂O₃, SiₓN_{y}, GaN, AlN, AlGaN, GaP, AlP, AlGaP, c-Si, etc. depending on the Gaussian beam wavelength and application requirement. The patterning of the flat lens or phase plate can be done by electron beam (ebeam) lithography, ultraviolet (UV) lithography or nanoimprint. The forming of the sub-wavelength structures may be done by plasma etching or ion-beam etching.

Various embodiments may relate to a methodology to design and fabricate a flat lens or a phase plate for Gaussian beam or laser beam transformation, in which the characterization of the performance of the flat lens or the phase plate is described.

Various embodiments may provide for an easy and practical method for the design and fabrications of a flat lens for Gaussian beam or laser beam transformation. Various embodiments may not require simulation of laser cavity to obtain the detailed phase information of the laser beam, which is tedious and not practical for real applications.

Various embodiments may provide for an easy and practical method for the design and fabrication of high efficiency flat lens for Gaussian beam or laser beam transformation, as compared to prior literature reports on Gaussian beam transformation using plasmonic structure, zone plates, or conventional optics with curvature. The flat lens fabricated has higher efficiency compared to Gaussian beam transformation using plasmonic structure and zone plates. The flat lens may be more compared than conventional optics with curvatures.

Various embodiments may provide an easy and practical method for the design and fabrication of a flat lens that can transform Gaussian beam or laser beam to any type of wave front, i.e. focusing, diverging or collimating.

Various embodiments may relate to guidelines in determining the diameter of the flat lens for Gaussian beam or laser beam transformation, which may provide flexibility in optical system design based on requirement and application scenario. The diameter of the flat lens may be set according to the requirement and application scenario, to be from 2 times beam waist, to 2.5 times, 3.14 times, 4.6 times or larger.

Various embodiments may relate to possible ways to construct the flat lens or phase plate according to designs described herein in terms of materials, shape, features, patterning and fabrication, and well as characterization, which are easier to implement and can produce high efficiency flat lens or phase plate. The flat lens may be formed by using an array of a-Si pillars on quartz substrate through a series of semiconductor processing with required profile in terms of diameter, height, side wall smoothness and uniformity provided and demonstrated.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

1. An optical system comprising:
a lens structure configured to generate an outgoing Gaussian beam based on an incoming Gaussian beam; and
a light source configured to provide the incoming Gaussian beam to the lens structure;
wherein the lens structure is a flat lens or a phase plate.

2. The optical system according to claim 1,
wherein the lens structure comprises a plurality of unit elements;
where the lens structure further comprises a substrate such that the plurality of unit elements is in contact with the substrate; and
wherein each of the plurality of unit elements has at least one dimension smaller than a wavelength of the incoming Gaussian beam.

3. The optical system according to claim 2, wherein each of the plurality of unit elements is any one selected from a group consisting of a pillar, a disk, a bar, a slot on the substrate, and a torus.

4. The optical system according to claim 2, wherein each of the plurality of unit elements has a cross-section of any one shape selected from a group consisting of a circle, an ellipse, a triangle, a square, an annular square, an annular ring, and a polygon.

5. The optical system according to claim 2, wherein the plurality of unit elements comprises any one material selected from a group consisting of amorphous silicon, titanium dioxide, aluminum oxide, hafnium oxide, niobium oxide, silicon nitride, gallium nitride, aluminum nitride, aluminum gallium nitride, gallium phosphide, aluminum phosphide, aluminum gallium phosphide, crystalline germanium, and crystalline silicon.

6. The optical system according to claim 1, wherein the outgoing Gaussian beam is a converging beam.

7. The optical system according to claim 1, wherein the outgoing Gaussian beam is a diverging beam.

8. The optical system according to claim 1, wherein the outgoing Gaussian beam is a collimated beam.

9. The optical system according to claim 1, wherein a ratio of a diameter of the lens structure to a radius of a beam waist of the incoming Gaussian beam is any value equal to or greater than 2.

10. The optical system according to claim 9, wherein the ratio of the diameter of the lens structure to the radius of the beam waist of the incoming Gaussian beam is equal to 2, 2.5, π, 4.6 or greater.

11. A method of forming an optical system, the method comprising:
forming a lens structure configured to generate an outgoing Gaussian beam based on an incoming Gaussian beam provided by a light source;
wherein the lens structure is a flat lens or a phase plate.

12. The method according to claim 11,
wherein the lens structure comprises a plurality of unit elements; and
wherein forming the lens structure includes determining dimensions and a position of each of the plurality of unit elements based on a phase change required to be provided by each of the plurality of unit elements.

13. The method according to claim 12, wherein the phase change required to be provided by each of the plurality of unit elements is determined based on a radius of a curvature of the incoming Gaussian beam (Rᵢₙ), a desired distance between the lens structure and a beam waist of the outgoing Gaussian beam (f), a wavelength of the incoming Gaussian beam (λ), a desired beam radius of the incoming Gaussian beam at the lens structure (w), and a type of the outgoing Gaussian beam desired.

14. The method according to claim 13, wherein the type of the outgoing Gaussian beam is any one selected from a diverging beam, a converging beam, and a collimated beam.

15. The method according to claim 12, wherein forming the lens structure further includes:
depositing a layer of lens material on a substrate; and
forming the plurality of unit elements by patterning the layer of lens material.

16. The method according to claim 15, wherein patterning the layer of lens material comprises:
forming a patterned resist layer on the layer of lens materials; and
etching the layer of lens material based on the patterned resist layer.

17. The method according to claim 15, wherein patterning the layer of lens material comprises:
depositing a resist layer on a hard mask layer;
patterning the resist layer to form a patterned resist layer;
forming a hard mask based on the hard mask layer using the patterned resist layer; and
etching the layer of lens materials based on the hard mask.

18. The method according to claim 12, wherein each of the plurality of unit elements has at least one dimension smaller than a wavelength of the incoming Gaussian beam.

19-20. (canceled)

21. The method according to claim 12, wherein the plurality of unit elements comprises any one material selected from a group consisting of amorphous silicon, titanium dioxide, aluminum oxide, hafnium oxide, niobium oxide, silicon nitride, gallium nitride, aluminum nitride, aluminum gallium nitride, gallium phosphide, aluminum phosphide, aluminum gallium phosphide, crystalline germanium, and crystalline silicon.

22. The method according to claim 11, wherein a ratio of a diameter of the lens structure to a radius of a beam waist of the incoming Gaussian beam is any value equal to or greater than 2.

23. (canceled)
